(19) United States
(12) Patent Application Publication
(10) Pub. No.: US 2017/0372732 A1
(43) Pub. Date: Dec. 28, 2017

(54) MAGNETIC RECORDING HEAD TEST FIXTURE HAVING WRAP-AROUND CONTACT PADS

(71) Applicant: HGST Netherlands B.V., Amsterdam (NL)

(72) Inventors: Kazue Kudo, Odawara (JP); Hiromi Shiina, Hitachi (JP); Toshihiro Ootaki, Odawara (JP); Kazuo Inaba, Ahigarashimogun Manazurumachi (JP)

(21) Appl. No.: 15/195,939

(22) Filed: Jun. 28, 2016

(51) Int. Cl. G11B 5/455; G01R 33/12

(52) U.S. Cl. CPC G11B 5/455; G01R 33/1207

(57) ABSTRACT

A test fixture for testing magnetic heads to be used in a magnetic data recording system. The test fixture includes a test fixture body that includes lead terminals. The lead terminals, which can be constructed of Si have a top surface and first and second laterally opposed sides. An electrically conductive material is formed over the lead terminal and extends down the sides of the lead terminal. Extending the lead terminal down the sides of the lead terminal as well as over the top surface provides improved adhesion of the electrically conductive lead material to the lead terminal. This improved adhesion is especially beneficial for use in such a test fixture, because the test fixture is designed to flex during use, which would otherwise contribute to de-lamination of the electrically conductive lead material from the lead terminal.

### FIELD OF THE INVENTION

The present invention relates to magnetic data recording, and more particularly to a device for holding a slider during testing of magnetic recording elements.

### BACKGROUND

At the heart of a computer is an assembly that is referred to as a magnetic disk drive. The magnetic disk drive includes a rotating magnetic disk, write and read heads that are suspended by a suspension arm adjacent to a surface of the rotating magnetic disk and an actuator that swings the suspension arm to place the read and write heads over selected tracks on the rotating disk. The read and write heads are directly located on a slider that has an air bearing surface (ABS). The suspension arm biases the slider into contact with the surface of the disk when the disk is not rotating, but when the disk rotates air is swirled by the rotating disk. When the slider rides on the air bearing, the write and read heads are employed for writing magnetic impressions to and reading magnetic impressions from the rotating disk. The read and write heads are connected to processing circuitry that operates according to a computer program to implement the writing and reading functions.

The write head includes at least one coil, a write pole and one or more return poles. When current flows through the coil, a resulting magnetic field causes a magnetic flux to flow through the coil, which results in a magnetic write field emitting from the tip of the write pole. This magnetic field is sufficiently strong that it locally magnetizes a portion of the adjacent magnetic media, thereby recording a bit of data. The write field then, travels through a magnetically soft under-layer of the magnetic medium to return to the return pole of the write head.

A magnetoresistive sensor such as a Giant Magnetoresistive (GMR) sensor, a Tunnel Junction Magnetoresistive (TMR) sensor or a scissor type magnetoresistive sensor can be employed to read a magnetic signal from the magnetic media. The magnetoresistive sensor has an electrical resistance that changes in response to an external magnetic field. This change in electrical resistance can be detected by processing circuitry in order to read magnetic data from the magnetic media.

Prior to assembly into the data recording system, the magnetic read sensor and magnetic write head formed on the slider can be tested to ensure that the their performance is within acceptable standards. Once their performance has been found to be within desired tolerance ranges, the slider and associated read/and write heads can be permanently installed into the data recording system by mounting the slider onto the suspension.

### SUMMARY

The present invention provides a test fixture that includes at least one lead terminal having first and second laterally opposed sides and a top surface. An electrically conductive lead material is formed over the top surface of the lead terminal and also extends down the sides of the lead terminal.

Extending the electrically conductive lead material down the sides of the lead terminal advantageously improves adhesion of the electrically conductive lead material to the lead terminal. This is especially advantageous, because the test fixture is designed to flex during use. This flexing of the test fixture would otherwise cause de-lamination of the electrically conductive lead material. However, forming the electrically conductive lead material so that it extends down the sides of the lead terminal prevents such de-lamination, thereby increasing the life and reliability of the test fixture.

These and other features and advantages of the invention will be apparent upon reading of the following detailed description of the embodiments taken in conjunction with the figures in which like reference numeral indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic illustration of a disk drive system in which the invention might be embodied;

FIG. 2 is an exploded view of a slider and suspension assembly for use in a magnetic data recording system;

FIG. 3 is a perspective view of a test fixture for holding a slider during testing of a magnetic read/write head formed thereon;

FIG. 4 is an exploded view of a slider, test fixture and suspension assembly;

FIG. 5a is a top down view of an etched blank of a test fixture and lead lines formed thereon;

FIG. 5b is an enlarged view of a portion of the etched bland of a text fixture of FIG. 5a;

FIG. 6 is a cross-sectional view of a portion of a text fixture as seen from line 6-6 of FIG. 5b;

FIGS. 7-13 are cross sectional views of a portion of a test fixture in various intermediate stages of manufacture in order to illustrate a method of manufacturing a magnetic test fixture; and

FIG. 14 is a cross sectional view of portions of a test fixture illustrating opposite ends of a lead structure formed thereon.

### DETAILED DESCRIPTION

The following description is of the best embodiments presently contemplated for carrying out this invention. This description is made for the purpose of illustrating the general principles of this invention and is not meant to limit the inventive concepts claimed herein.

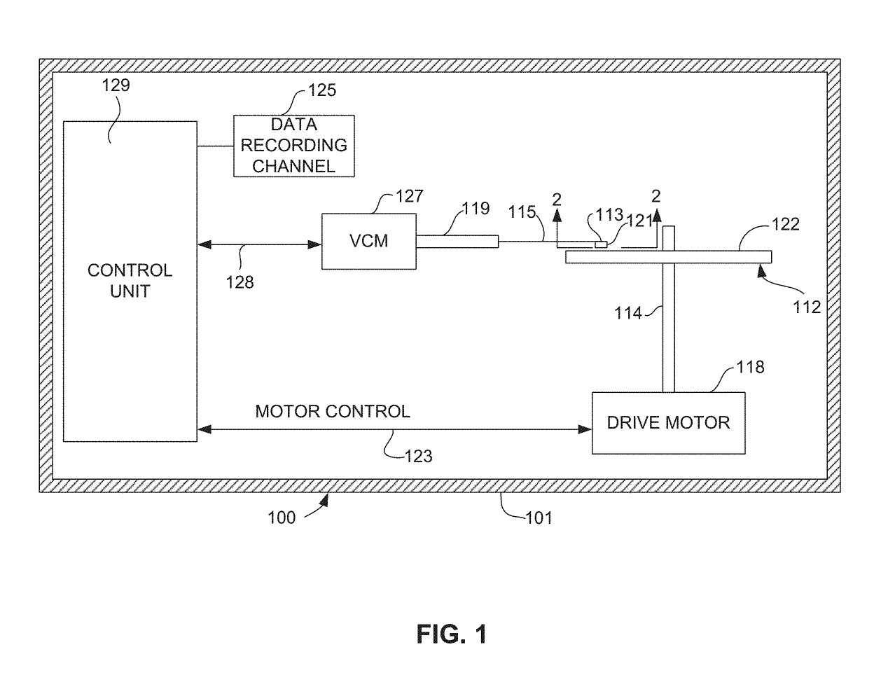

Referring now to FIG. 1, there is shown a disk drive 100. The disk drive 100 includes a housing 101. At least one rotatable magnetic disk 112 is supported on a spindle 114 and rotated by a disk drive motor 118. The magnetic recording on each disk may be in the form of annular patterns of concentric data tracks (not shown) on the magnetic disk 112.

At least one slider 113 is positioned near the magnetic disk 112, each slider 113 supporting one or more magnetic head assemblies 121. As the magnetic disk rotates, slider 113 moves in and out over the disk surface 122 so that the magnetic head assembly 121 can access different tracks of the magnetic disk where desired data are written. Each slider 113 is attached to an actuator arm 119 by way of a suspension 115. The suspension 115 provides a slight spring force which biases the slider 113 against the disk surface 122. Each actuator arm 119 is attached to an actuator means 127. The actuator means 127 as shown in FIG. 1 may be a voice coil motor (VCM). The VCM comprises a coil movable within a fixed magnetic field, the direction and speed of the coil movements being controlled by the motor current signals supplied by the controller 129.

During operation of the disk storage system, the rotation of the magnetic disk 112 generates an air bearing between the slider 113 and the disk surface 122, which exerts an upward force or lift on the slider. The air bearing thus counter-balances the slight spring force of the suspension 115 and supports the slider 113 off and slightly above the disk surface by a small, substantially constant spacing during normal operation.

The various components of the disk storage system are controlled in operation by control signals generated by control unit 129, such as access control signals and internal clock signals. Typically, the control unit 129 comprises logic control circuits, and a microprocessor. The control unit 129 generates control signals to control various system operations such as drive motor control signals on line 123 and head position and seek control signals on line 128. The control signals on line 128 provide the desired current profiles to optimally move and position the slider 113 to the desired data track on the media 112. Write and read signals are communicated to and from write and read heads 121 by way of recording channel 125.

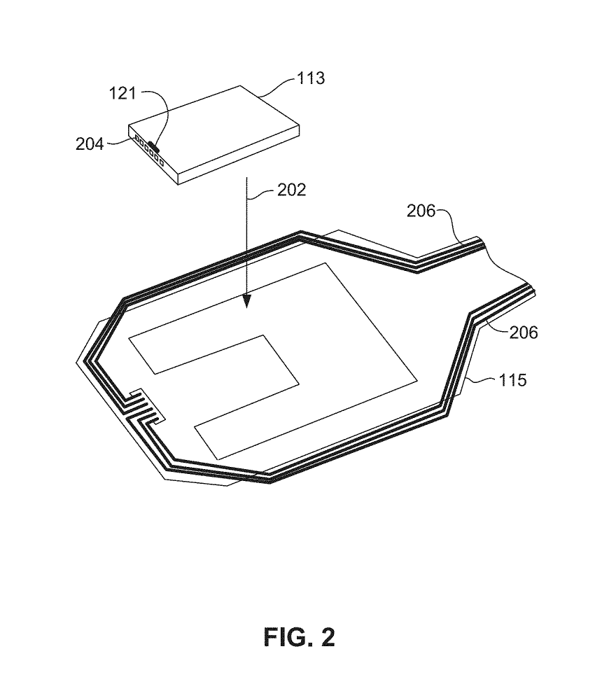

FIG. 2 shows an exploded view of a slider assembly 113 and a portion of a suspension assembly 115. During manufacture, the slider 113 is mounted to the suspension assembly as indicated by arrow 202. The slider 113 has a magnetic read/write head 121 formed at a trailing edge of the slider 113, and the read/write head 121 is electrically connected with contact pads 204 by electrically conductive lead lines that are not shown in FIG. 2.

Once the slider 113 is permanently mounted to the suspension assembly 115, the contact pads 204 electrically connect with lead lines 206 formed on the suspension assembly 115, whereby the read/write head 121 can electrically communicate with processing circuitry 129, 125 (FIG. 1). Once the slider 113 has been permanently mounted onto the suspension 115, it cannot be easily removed. Therefore, it is desirable to test the performance of the read/write head 121 prior to permanently mounting the slider 113 to the suspension assembly 115. Should the read/write head 121 not fall within desired performance parameters, then the slider 113 can be scrapped and replaced with another slider 113 and read/write head 121.

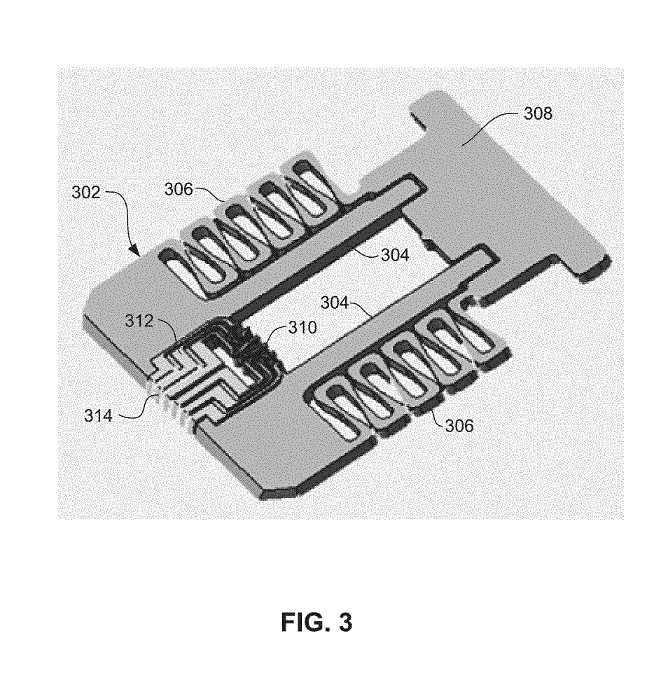

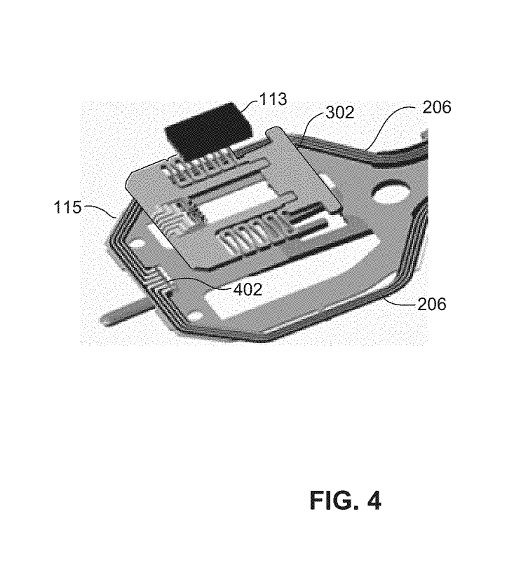

FIG. 3 shows a perspective view of test fixture 302, and FIG. 4 is an exploded view of the test fixture 302 suspension 115, and slider 113. As seen in FIG. 4, the test fixture 302 is configured to receive the slider 113 and to temporarily mount within the suspension assembly 115. As seen more clearly in FIG. 3, the test fixture 302 has a guide channel 304 for receiving the slider 113. The test fixture 302 also has springs 306 and an engagement tab 308. To load a slider 113 into the test fixture 302, the engagement tab 308 can be pulled outward and the slider 113 inserted into the guide channel 304. When the engagement tab 308 is released, the springs 306 will bias the engagement tab 308 toward the slider, securely holding the slider 113 in place.

The test fixture 302 also has slider side electrically conductive contact pads 310 that are electrically connected with suspension side electrically conductive contact pads 314 by electrically conductive lead lines 312. These will be described in greater detail herein below. When the slider 113 is held within the test fixture 302, the contact pads 204 of the slider 113 (FIG. 2) will engage the contact pads 310 of the test fixture 302. Similarly, when the test fixture 302 is temporarily mounted on the suspension assembly 115 as shown in FIG. 4, the suspension side contact pads 314 will engage contact pads 402 of the suspension assembly 115. This, therefore, allows the contact pads 204 of the slider 113 to be temporarily electrically connected with the lead lines 206, thereby allowing the performance of the magnetic read/write heads 121 to be tested prior to final, permanent mounting of the slider 113 to the suspension assembly 115.

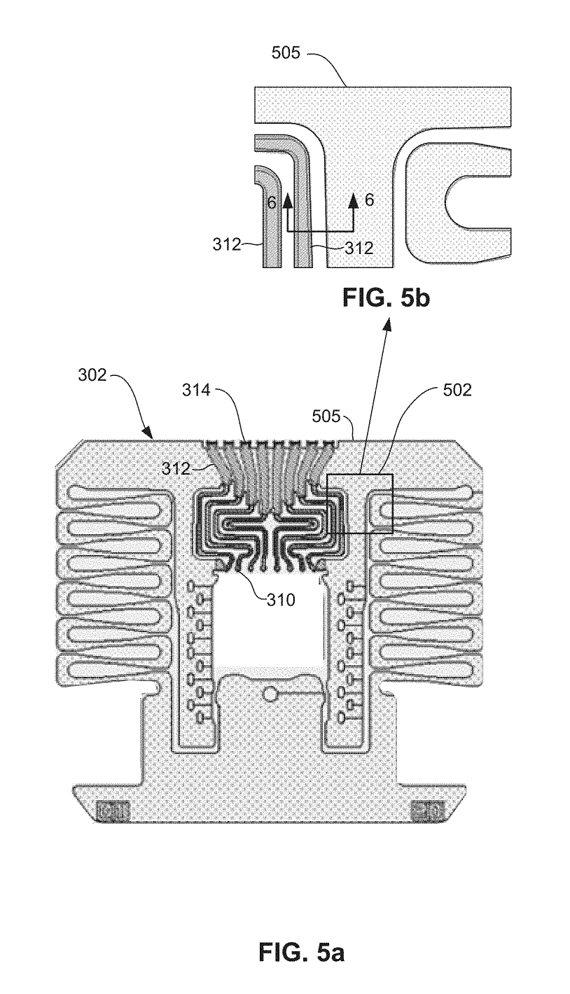

FIG. 5a shows a top down view of the test fixture 302 including a test fixture body portion 505, lead lines 312, slider side contact pads 310 and suspension assembly side lead pads 314. FIG. 5b is an enlarged view of the area shown in box 502 of FIG. 5a. As can be seen, FIG. 5b shows a portion of two lead lines 312.

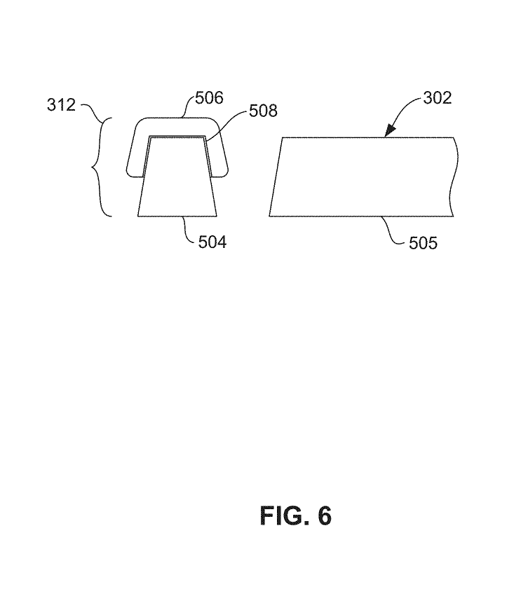

FIG. 6 shows a cross sectional view of a portion of the test fixture 302 with lead lines 312 as seen from line 6-6 of FIG. 5b. FIG. 6 shows the test fixture body portion 505 and an electrically conductive lead portion 312. The lead portion 312 includes a lead terminal portion 504 with an electrically conductive lead material 506 formed there-over. A seed layer 508 may also be provided beneath the electrically conductive lead material 506. The test fixture body 505 and lead terminal 504 can be formed of a material such as Si, which allows it to be sufficiently flexible and also sufficiently stiff to effectively hold the slider 113 (FIG. 4) therein. The electrically conductive material 506 can be constructed of a material such as Au, which has good electrical conductivity, ductility and corrosion resistance. The seed layer 508 can be an electrically conductive material that can be deposited by a process such as sputter deposition.

As can be seen in FIG. 6, the electrically conductive lead material 506 (and seed layer 508) wrap around the sides of the terminal structure 504, rather than only being on the top of the terminal structure 504. While this wrapping around of the lead material 506 requires some additional manufacturing complexity and would not, therefore, be an obvious design choice, this structure provides great benefit with regard to function and reliability of the test fixture 302. As those skilled in the art will appreciate, operation of the test fixture 302 requires a great deal of flexure of the structure 504 underlying the lead material 506. Further, the test fixture 302 is designed to be used tens of thousands of times. Therefore, the structure is preferably very durable. If the electrically conductive lead material 506 were only plated at the top of the underlying terminal structure 504 it would be prone to de-lamination and would have insufficient robustness and reliability. Wrapping the lead material 506 around the terminal structure 504 so that it is applied to the sides of the terminal 504 as well as the top greatly improves adhesion, thereby ensuring that the test fixture will last through many needed test cycles. Further, the wrap around structure of the lead layer 506 improves electrical conduction by increasing the amount of electrically conductive material. Preferably, the electrically conductive lead material 506 and seed layer 508 extend ⅓ to ⅔ of the way down the sides of the lead terminal structure 504, or about half way down the sides of the lead terminal structure 504.

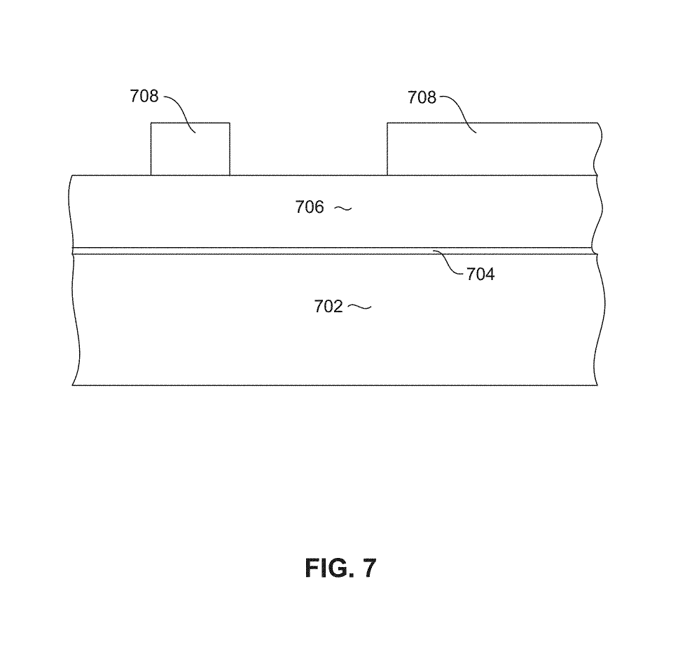

FIGS. 7-13 show a test fixture in various intermediate stages of manufacture in order to illustrate a method of manufacturing a test fixture with wrap-around lead material such as described above. With particular reference to FIG. 7, a substrate 702 is formed. This substrate 702 can be a material such as Si which will be later etched away, as will be seen. An etch stop layer 704 is deposited over the substrate 702. The etch stop layer 704 can be a material such as SiO₂ that is resistant to removal by reactive ion etching. Then, a layer of material 706 that will make up the body of the test fixture 302 (FIG. 5a) is deposited over the etch stop layer 704. The text fixture material 706 can be a material such as Si. A mask structure 708 is then formed over the test fixture material 706. The mask is patterned with openings that are configured to define the shape of a test fixture, such as that shown in FIG. 5a.

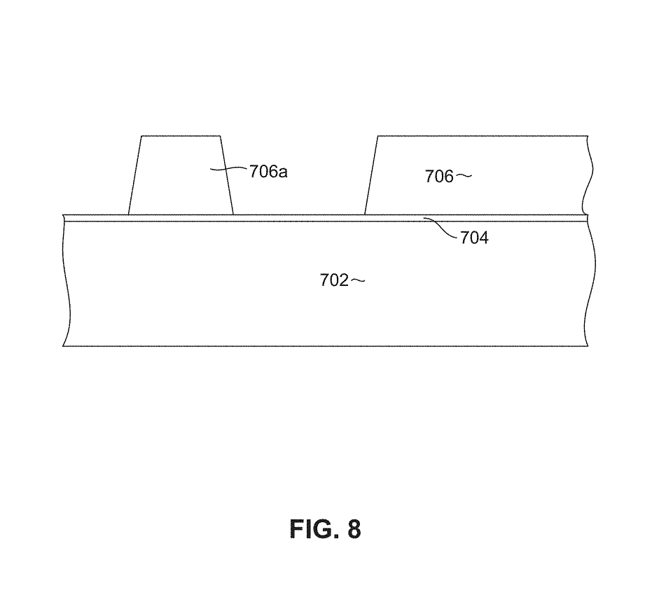

After the mask 708 has been formed, a reactive ion etching (RIE) can be performed to remove portions of the test fixture material 706 that are not protected by the mask 708, thereby leaving a structure as shown in cross-section in FIG. 8. The mask 708 can be removed by a suitable mask liftoff process such as chemical liftoff. Again, this etching process etches the test fixture material 706 into a shape such as that shown in top-down view in FIG. 5a and leaves a lead terminal portion 706a (FIG. 8) in a region where an electrically conductive lead is to be formed. The reactive ion etching terminates at the etch stop layer. In addition to reactive ion etching, other suitable material removal processes could be used to remove the exposed portions of the layer 706.

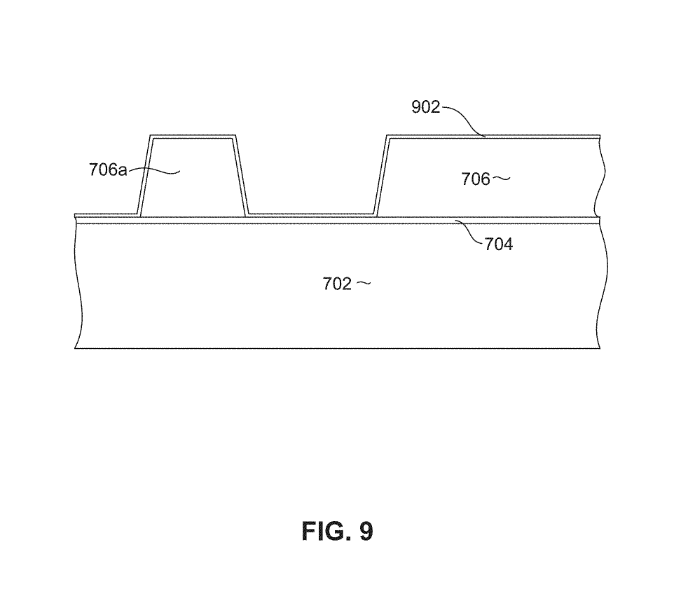

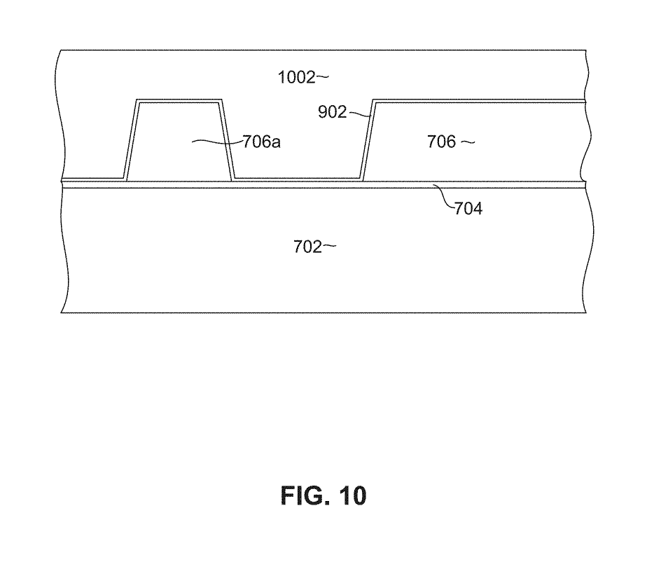

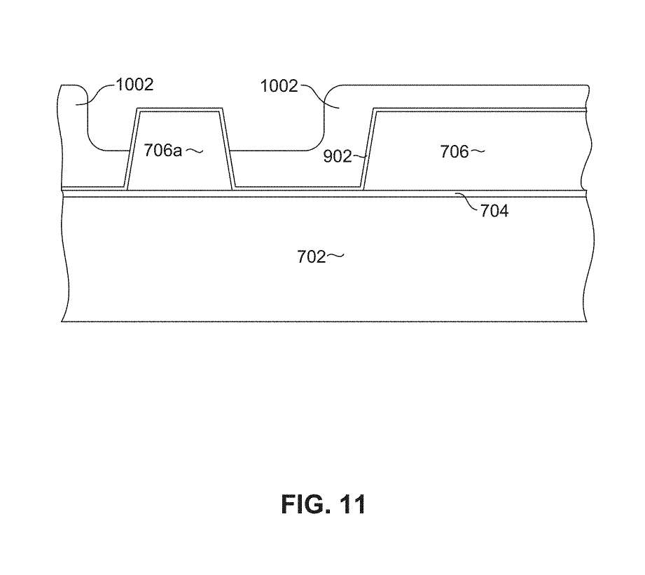

With reference now to FIG. 9, an electrically conductive seed layer 902 is deposited, such as by sputter deposition. This layer 902 will provide an electroplating seed layer. Then, with reference to FIG. 10, a layer of photoresist material 1002 is deposited. The photoresist 1002 is exposed and developed so as to recess the photoresist only in the region of the lead terminal 706a, as shown in FIG. 11. The exposure and development of the photoresist can be controlled so as to recess the photoresist 1002 and expose the lead terminal portion 706a to a desired degree only in the region of the lead terminal 706a. Preferably, the thickness of the photoresist 1002 is reduced down to about one half of the thickness of the lead terminal portion 706a as shown in FIG. 11 or from ⅓ to ⅔ the thickness of the lead terminal portion 706a as measured in a vertical direction in FIG. 11.

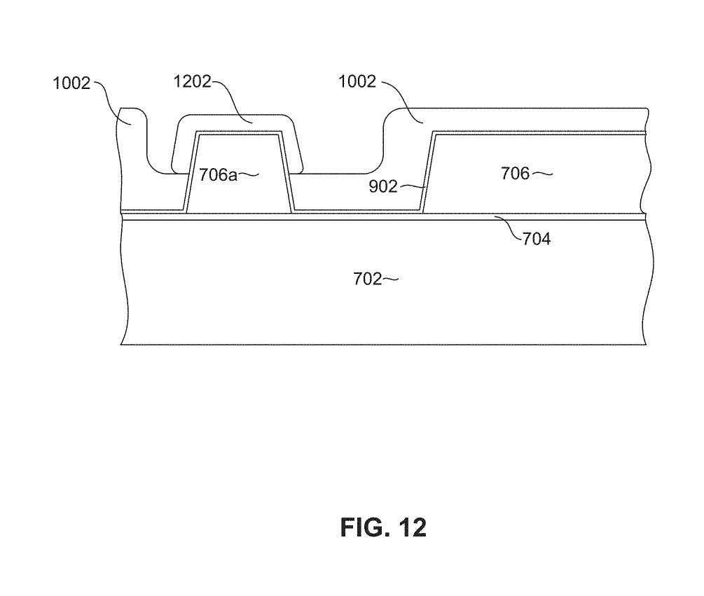

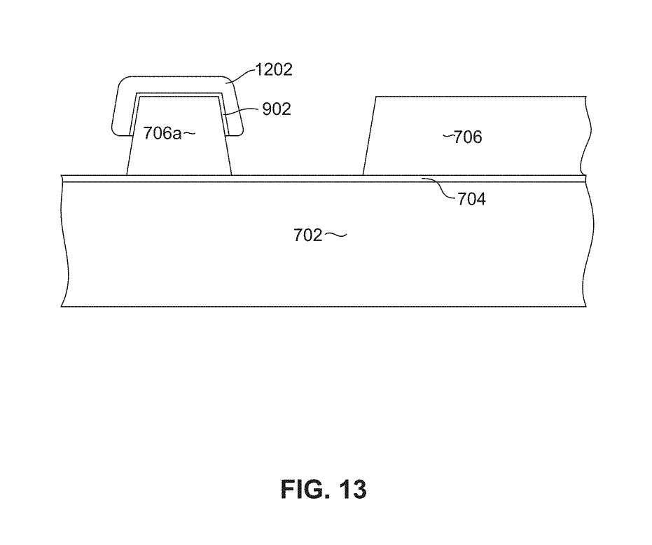

Then, with reference to FIG. 12, a layer of electrically conductive lead material 1202 is electroplated onto the seed layer 902 over the lead terminal portion 706a. As shown, the lead material 1202 will only be electroplated in regions where the seed layer 902 is exposed. The lead material 1202 can be a material having good electrical conductivity and good corrosion resistance. The lead material 1202 is preferably Au. After the lead material 1202 has been electroplated, the photoresist material 1002 and the seed layer material 902 can be removed by a process such as a chemical removal process, thereby leaving a structure as shown in FIG. 13. As can be seen in FIG. 13, the lead material 1202 wraps around the sides of the lead terminal portion 706a as desired and is only formed in the region of the lead terminal portion 706a. After the above processes have been performed, the underlying substrate 702 and etch stop layer 704 can be removed, leaving the fixture body 706 free standing.

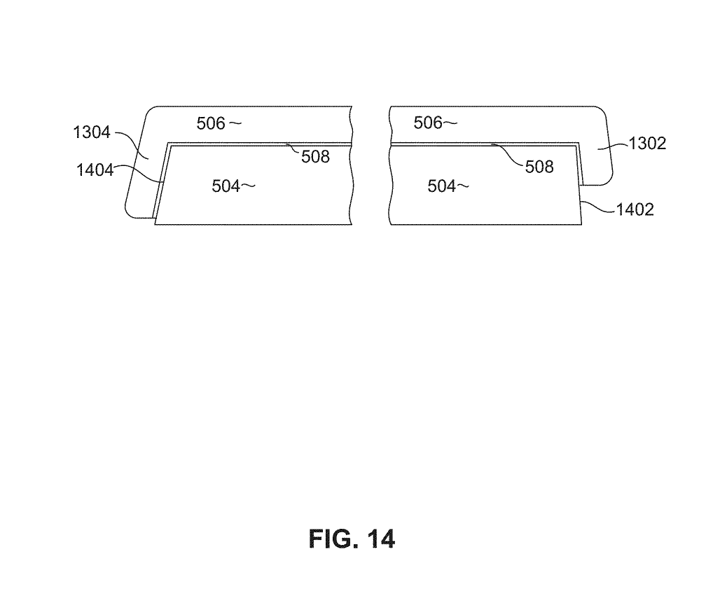

FIG. 14 shows a cross sectional view of a lead structure 312 showing opposite ends of the lead structure 312. In FIG. 13, a first end is a slider end contact 1302 that is designed to make contact with a lead pad 204 of a slider 113 (FIG. 2). The opposite end is a suspension side contact 1304 that is configured to make electrical contact with a suspension 115 (FIG. 2). The lead material 506 extends down an end surface 1402 at the slider end contact side 1302, and also extends down an end surface 1404 at the suspension contact side 1304. As can be seen in FIG. 13, the electrical lead material 506 extends further down the end surface 1304 than it does down the end surface 1306. Preferably, the lead material 506 extends about one half of the way down the end surface 1402 and about ⅔ down the end surface 1404. This difference can be accomplished by changing the exposure and development conditions performed on the photoresist in the process described above with reference to FIG. 11.

While various embodiments have been described above, it should be understood that they have been presented by way of example only and not limitation. Other embodiments falling within the scope of the invention may also become apparent to those skilled in the art. Thus, the breadth and scope of the inventions should not be limited by any of the above-described exemplary embodiments, but should be defined only in accordance with the following claims and their equivalents.

What is claimed is:

1. A test fixture, comprising:
a terminal structure having first and second laterally opposed sides and a top surface extending from the first side to the second side; and
an electrically conductive lead material formed over the top surface of the terminal structure and extending down each of the first and second sides.

2. The test fixture as in claim 1, wherein the terminal structure comprises Si.

3. The test fixture as in claim 1, further comprising an electrically conductive seed layer located between the terminal structure and the electrically conductive lead material.

4. The test fixture as in claim 1, wherein the electrically conductive lead material comprises Au.

5. The test fixture as in claim 1, wherein the electrically conductive lead material extends about halfway down each of the sides of the terminal structure.

6. The test fixture as in claim 1, wherein the electrically conductive lead material extends ⅓ to ⅔ of the way down each of the sides of the terminal structure.

7. The test fixture as in claim 1, wherein the terminal structure further comprises an end surface and wherein the electrically conductive lead material extends down the end surface of the terminal structure.

8. The test fixture as in claim 1, wherein the terminal structure further comprises first and second end surfaces, and wherein:
the electrically conductive lead material extends down each of the first and second end surfaces, and
the electrically conductive lead material extends further down the first end surface than it does down the second end surface.

9. The test fixture as in claim 8, wherein the electrically conductive lead material extends about half way down the second end surface and at least ⅔ down the first end surface.

10. The test fixture as in claim 1, wherein the test fixture is configured to hold a slider and temporarily electrically connect the slider with a suspension assembly.

11. A method of manufacturing a test fixture, comprising:
providing a substrate;
forming a fixture body over the substrate, the fixture body including a lead terminal portion having a top surface and first and second laterally opposed sides;
depositing an electrically conductive seed layer;
depositing a photoresist over the electrically conductive seed layer;
exposing and developing the photoresist to reduce the thickness of the photoresist in a region of the lead terminal; and
electroplating an electrically conductive material.

12. The method as in claim 11, wherein the exposing and developing the photoresist exposes the electrically conductive seed layer on the lead terminal.

13. The method as in claim 11, further comprising, after electroplating the electrically conductive lead material, removing the photoresist.

14. The method as in claim 11, wherein the exposing and developing of the photoresist only reduces the thickness of the photoresist in the region of the lead terminal portion.

15. The method as in claim 11, wherein the exposing and developing of the photoresist exposes the electrically conductive seed layer only in the region of the lead terminal portion.

16. The method as in claim 11, wherein the exposing and developing of the photoresist reduces the thickness of the photoresist in the region of the lead terminal to a thickness that is about half the thickness of the lead terminal portion.

17. The method as in claim 11, wherein the test fixture body comprises Si.

18. The method as in claim 11, wherein the forming of the test fixture further comprises:
depositing an etch stop layer over the substrate;
depositing a test fixture material over the substrate;
photolithographically patterning a mask structure over the test fixture material; and
performing an etching process to remove portions of the test fixture material that are not protected by the mask structure.

19. The method as in claim 18, wherein the test fixture material comprises Si.

20. The method as in claim 11, further comprising:
after electroplating the electrically conductive material, removing the photoresist; and
removing portions of the seed material that are not protected by the electrically conductive material.
